(19) United States
(12) Patent Application Publication
(10) Pub. No.: US 2020/0303009 A1
(43) Pub. Date: Sep. 24, 2020

(54) SEMICONDUCTOR DEVICE

(71) Applicants: HONDA MOTOR CO., LTD., Tokyo (JP); TOKYO INSTITUTE OF TECHNOLOGY, Tokyo (JP)

(72) Inventors: Koji Sakui, Wako-shi (JP); Takayuki Ohba, Tokyo (JP)

(21) Appl. No.: 16/817,669

(22) Filed: Mar. 13, 2020

(30) Foreign Application Priority Data
Mar. 18, 2019 (JP) 2019-050060

(51) Int. Cl. G11C 16/08; H01L 23/48; G11C 16/04; G11C 16/26

(52) U.S. Cl. CPC G11C 16/08; G11C 16/26; G11C 16/0483; H01L 23/481

(57) ABSTRACT

A semiconductor device includes: a memory semiconductor chip that includes a plurality of memory cells; a planar buffer chip as a semiconductor chip that includes a plurality of buffer circuits which hold data read from the memory cell or written to the memory cell and which output the held data in accordance with a number of readout lines of the plurality of memory cells; and an electrical connection structure that electrically connects the readout line of the memory cell of the memory semiconductor chip to the buffer circuit of the planar buffer chip in a thickness direction of the memory semiconductor chip and the planar buffer chip.

### CROSS-REFERENCE TO RELATED APPLICATION

Priority is claimed on Japanese Patent Application No. 2019-050060, filed on Mar. 18, 2019, the contents of which are incorporated herein by reference.

### BACKGROUND

### Field of the Invention

The present invention relates to a semiconductor device.

### Background

A semiconductor device such as a flash memory includes a page buffer circuit for performing parallel access of reading or writing of data per page unit having a predetermined data length and allows page-by-page access (for example, refer to Japanese Unexamined Patent Application, First Publication No. 2000-100181).

### SUMMARY

However, in the semiconductor device of the related art as described above, for example, a bit line of a memory cell and the page buffer circuit are connected by a wiring on a plane of a semiconductor chip, and therefore, the data length that can be accessed in parallel is limited by a wiring pitch on the plane. Therefore, in the semiconductor device of the related art, it is difficult to speed up the access.

An object of an aspect of the present invention is to provide a semiconductor device capable of speeding up access.

An aspect of the present invention is a semiconductor device including: a memory semiconductor chip that includes a plurality of memory cells; a planar buffer chip as a semiconductor chip that includes a plurality of buffer circuits which hold data read from the memory cell or written to the memory cell and which output the held data in accordance with a number of readout lines of the plurality of memory cells; and an electrical connection structure that electrically connects the readout line of the memory cell of the memory semiconductor chip to the buffer circuit of the planar buffer chip in a thickness direction of the memory semiconductor chip and the planar buffer chip.

The above semiconductor device may include a buffer decoder part that is configured to select one from a predetermined number of readout lines and connects the selected one readout line to the buffer circuit.

In the above semiconductor device, the memory semiconductor chip may have a plurality of semiconductor chips including the memory cell that are laminated in a thickness direction, and the electrical connection structure may electrically connect the plurality of laminated semiconductor chips to the planar buffer chip.

In the above semiconductor device, the electrical connection structure may be a penetration electrode that penetrates through the memory semiconductor chip and the planar buffer chip in a thickness direction and connects the memory semiconductor chip to the planar buffer chip using a conductor.

According to an aspect of the present invention, it is possible to speed up the access.

### BRIEF DESCRIPTION OF THE DRAWINGS

FIG. 1 is a configuration view showing an example of a semiconductor device according to a first embodiment.

FIG. 2 is a functional block diagram showing an example of the semiconductor device according to the first embodiment.

FIG. 3 is a configuration view showing an example of a memory cell array according to the first embodiment.

FIG. 4 is a view showing a configuration example of the memory cell array in an x1-x2 direction according to the first embodiment.

FIG. 5 is a view showing a configuration example of the memory cell array in a y1-y2 direction according to the first embodiment.

FIG. 6 is a view showing a configuration example when viewed from the top of the memory cell array according to the first embodiment.

FIG. 7 is a cross-sectional view showing an example of connection between a memory semiconductor chip and a planar buffer chip according to the first embodiment.

FIG. 8 is a configuration view showing an example of a semiconductor device according to a second embodiment.

FIG. 9 is a configuration view showing an example of a buffer decoder part according to the second embodiment.

FIG. 10 is a configuration view in a case of selecting a Y0 line of a decoder switch part according to the second embodiment.

FIG. 11 is a configuration view in a case of selecting an X0 line of the decoder switch part according to the second embodiment.

### DESCRIPTION OF THE EMBODIMENTS

Hereinafter, a semiconductor device according to an embodiment of the present invention will be described with reference to the drawings.

### First Embodiment

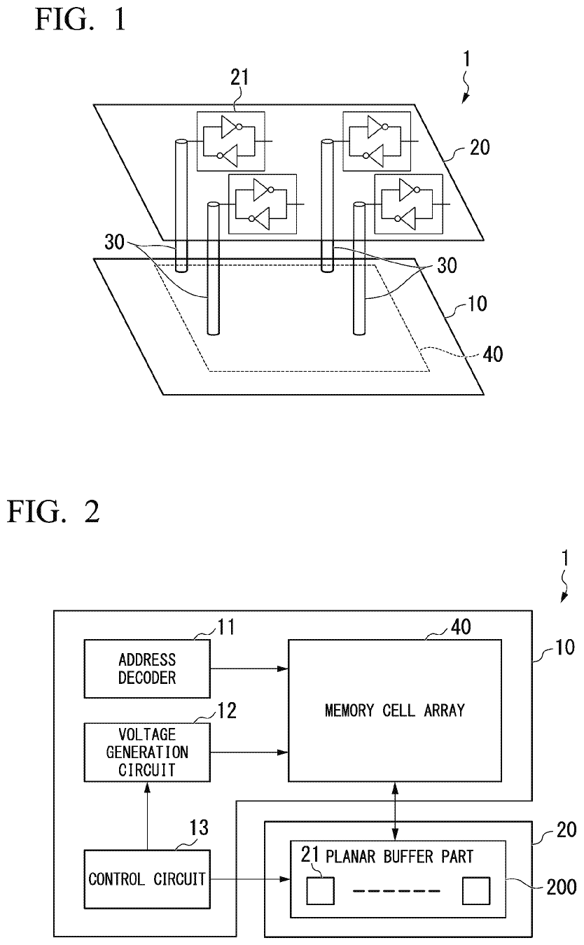

FIG. 1 is a configuration view showing an example of a semiconductor device 1 according to a first embodiment.

As shown in FIG. 1, the semiconductor device 1 is, for example, a NAND-type flash memory device and includes a memory semiconductor chip 10, a planar buffer chip 20, and a TSV (Through-Silicon Via) 30.

The memory semiconductor chip 10 is a semiconductor chip that includes a memory cell array 40 having a plurality of memory cells MC (for example, flash memory cells).

The memory cell array 40 is, for example, a three-dimensional NAND-type flash memory and has a configuration obtained by laminating semiconductor chips (memory semiconductor chips) including the plurality of memory cells MC in a thickness direction. The detailed configuration of the memory cell array 40 will be described later.

The planar buffer chip 20 is a semiconductor chip including a plurality of buffer circuits 21 in accordance with the number of bit lines (readout lines) of the memory cell MC.

The buffer circuit 21 is a circuit that holds data read from the memory cell MC and data written to the memory cell MC. When reading, the buffer circuit 21 outputs the held data as readout data. When writing, the buffer circuit 21 outputs the held data as write data to the memory cell MC.

The TSV 30 (an example of an electrical connection structure) is a bumpless penetration electrode that penetrates through the memory semiconductor chip 10 and the planar buffer chip 20 in a thickness direction and connects the memory semiconductor chip 10 to the planar buffer chip 20 using a conductor. The TSV 30 electrically connects a bit line of the memory cell MC to the buffer circuit 21 in a thickness direction of the memory semiconductor chip 10 and the planar buffer chip 20.

FIG. 2 is a functional block diagram showing an example of the semiconductor device 1 according to the present embodiment.

As shown in FIG. 2, the semiconductor device 1 includes an address decoder 11, a voltage generation circuit 12, a control circuit 13, a planar buffer part 200, and a memory cell array 40.

The address decoder 11 decodes input address information and outputs a control signal for selecting the memory cell MC of the memory cell array 40.

The voltage generation circuit 12 generates an erase voltage required for erasing data and a write voltage required for writing data and supplies the generated erase voltage and the generated write voltage to the memory cell array 40 which is a flash memory.

The control circuit 13 is a logic circuit that controls the semiconductor device 1 in response to an input from the outside. The control circuit 13 controls, for example, reading data from the memory cell array 40, erasing data of the memory cell array 40, and writing data to the memory cell array 40.

In order to collectively read or write data of a predetermined data length (bit width), the planar buffer part 200 includes a buffer circuit 21 in accordance with the predetermined data length (bit width). In the present embodiment, the data of the predetermined data length (bit width) is defined as a “page”, and the planar buffer part 200 holds page data.

The buffer circuit 21 in the present embodiment is connected to a bit line of the memory cell array 40 that is drawn in the thickness direction by the TSV 30, and a plurality of buffer circuits 21 are arranged two-dimensionally on a plane of the planar buffer chip 20.

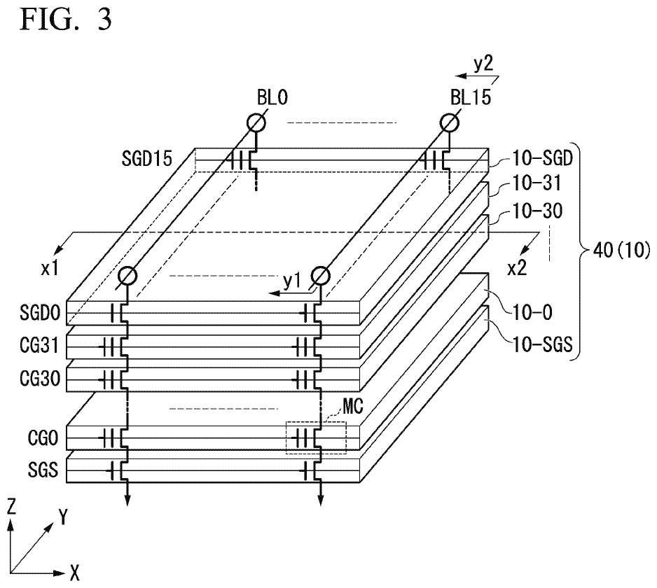

Next, the configuration of the memory cell array 40 according to the present embodiment will be described with reference to FIG. 3 to FIG. 6.

FIG. 3 is a configuration view showing an example of the memory cell array 40 according to the present embodiment.

As shown in FIG. 3, in the memory cell array 40, a plurality of gate plate electrodes (10-SGS, 10-0, . . . , 10-30, 10-31, 10-SGD) are laminated in a thickness direction (Z-axis direction). The plurality of gate plate electrodes (10-SGS, 10-0, . . . , 10-30, 10-31, 10-SGD) is an example of a plurality of semiconductor chips.

In FIG. 3, the direction of cell gate signal lines (CG0 to CG31) of the memory cell array 40 is defined as an X-axis direction, and a bit line direction is defined as a Y-axis direction. The chip surface of gate plate electrodes (10-SGS, 10-0, . . . , 10-30, 10-31, 10-SGD) is defined as an XY plane, and a thickness direction is defined as a Z-axis direction. The whole of a plurality of gate plate electrodes (10-SGS, 10-0, . . . , 10-30, 10-31, 10-SGD) constitutes the memory semiconductor chip 10.

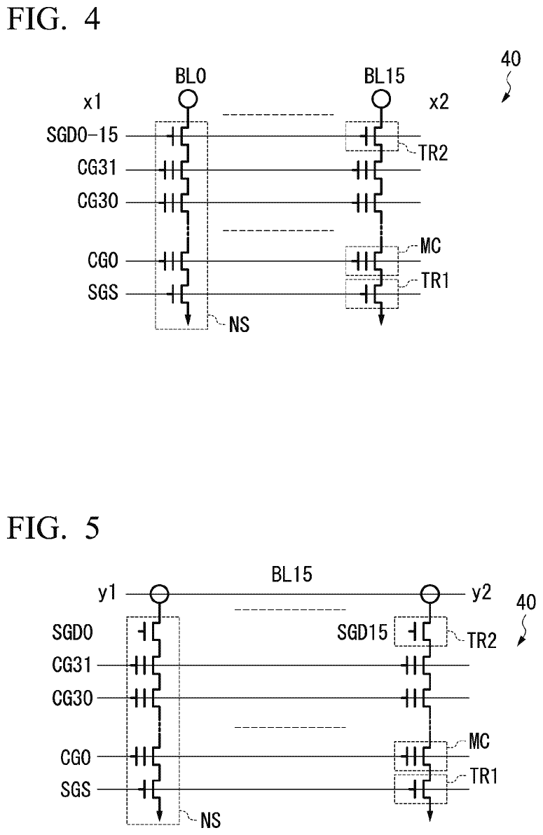

FIG. 4 shows a configuration example in an x1-x2 direction of FIG. 3 of memory cell array 40.

As shown in FIG. 4, the memory cell array 40 includes a NAND string NS in which a plurality of memory cells MC and selection transistor (TR1, TR2) are connected together in series.

In the NAND string NS, for example, a grounding selection transistor TR1, sixteen memory cells MC, and a data selection transistor TR2 are connected in series between a bit line (BL0 to BL15) and a GND (ground) line.

The grounding selection transistor TR1 is an NMOS transistor (N-type MOSFET (Metal-Oxide-Semiconductor Field-Effect Transistor)) arranged between the sixteen memory cells MC and the GND line. An SGS signal line is connected to a gate terminal of the grounding selection transistor TR1, and the grounding selection transistor TR1 is controlled by an SGS signal.

The data selection transistor TR2 is an NMOS transistor arranged between the bit line and the sixteen memory cells MC. One of SGD0 to SGD15 signal lines is connected to a gate terminal of the data selection transistor TR2, and the data selection transistor TR2 is controlled by one of SGD0 to SGD15 signals.

The sixteen memory cells MC are connected in series between the grounding selection transistor TR1 and the data selection transistor TR2.

A cell gate signal line (CG0 to CG31) is connected to each gate terminal of the sixteen memory cells MC.

Each connection between the grounding selection transistor TR1, the sixteen memory cells MC, and the data selection transistor TR2 is made in a thick direction (Z-axis direction) so as to penetrate through the plurality of gate plate electrodes (10-SGS, 10-0, . . . , 10-30, 10-31, 10-SGD) by a cell pillar CP which is a penetration electrode.

The SGD0 to SGD15 signals, the CGS signal, and CG0 to CG31 signals are generated by the address decoder 11 and the control circuit 13 described above.

FIG. 5 shows a configuration example in a y1-y2 direction of FIG. 3 of the memory cell array 40.

As shown in FIG. 5, similarly to the example shown in FIG. 4, the memory cell array 40 includes a NAND string NS in which a plurality of memory cells MC and a selection transistor (TR1, TR2) are connected together in series.

In the example shown in FIG. 5, sixteen NAND strings NS are connected to a bit line BL15, and a signal line of one of SGD0 to SGD15 signals is connected to a gate terminal of a data selection transistor TR2 of each NAND string NS.

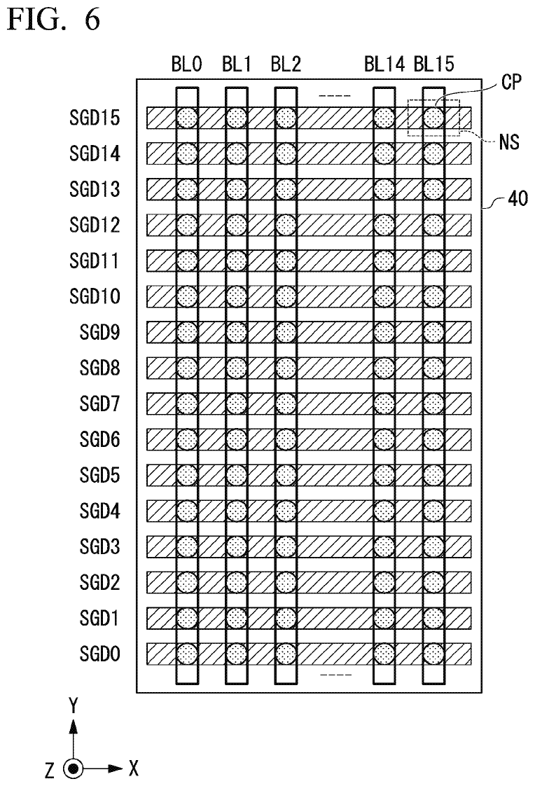

FIG. 6 is a view showing a configuration example when viewed from the top of the memory cell array 40 in the present embodiment.

As shown in FIG. 6, a plurality of NAND strings NS are arranged in a matrix manner, and in each NAND string NS, thirty-two memory cells MC are connected by a cell pillar CP that penetrates through a plurality of gate plate electrode (10-SGS, 10-0, . . . , 10-30, 10-31, 10-SGD) laminated in a thickness direction (Z-axis direction).

The plurality of NAND strings NS are connected for each bit line (BL0 to BL15) and are connected to one buffer circuit 21 described above for each bit line.

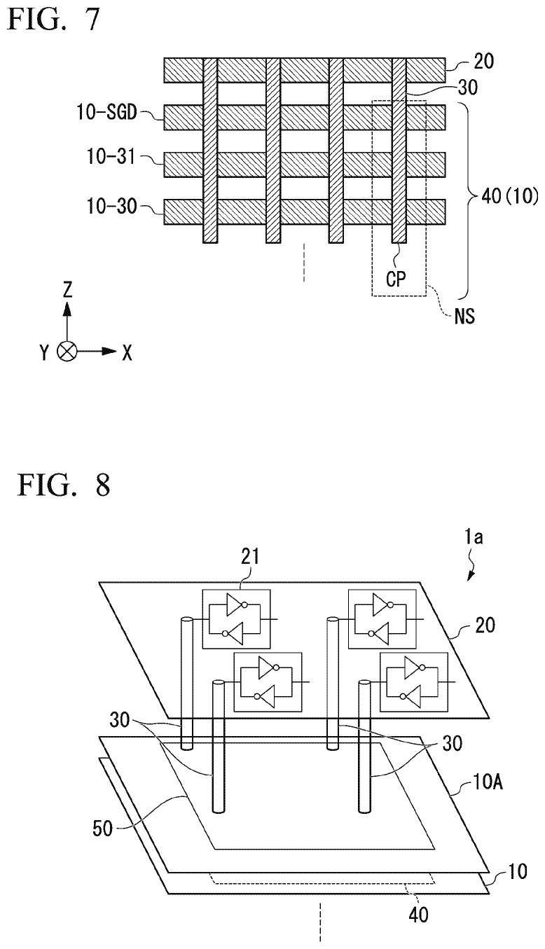

FIG. 7 is a cross-sectional view showing a connection example between the memory semiconductor chip 10 and the planar buffer chip 20 in the present embodiment.

As shown in FIG. 7, the memory semiconductor chip 10 (memory cell array 40) and the planar buffer chip 20 are electrically connected by the TSV 30 that penetrates through the planar buffer chip 20. The memory cell MC and the selection transistor (TR1, TR2) of the NAND string NS are electrically connected by the cell pillar CP that penetrates through each gate plate electrode (10-SGS, 10-0, . . . , 10-30, 10-31, 10-SGD).

In this way, the memory cell array 40 in the present embodiment is a three-dimensional flash memory in which the memory cells MC are connected together in the thickness direction by the cell pillar CP.

Next, an operation of the semiconductor device 1 according to the present embodiment will be described with reference to the drawings.

In FIG. 2 described above, in reading out data from the semiconductor device 1, when address information and, for example, a data readout command are input to the semiconductor device 1, first, the address decoder 11 generates the SGD0 to SGD15 signals, the SGS signal, and the CG0 to CG31 signals for selecting a memory cell MC to be read out on the basis of the input address information.

Specifically, the address decoder 11 selects the NAND string NS by allowing one of the SGD0 to SGD15 signals to be in a high state and the rest of the signals to be in a low state. The address decoder 11 selects one memory cell MC of the selected NAND string NS by allowing one of the CG0 to CG31 signals to be in a low state and the rest of the signals to be in a high state.

From the selected memory cell MC, “0” or “1” can be read out depending on whether or not a current flows in an OFF state in which the gate terminal is in the low state. The “0” or “1” data held by the memory cell MC is input to the buffer circuit 21 via the bit line and the TSV 30 and is held by the buffer circuit 21. Here, data of a predetermined data length (bit width) is read out in parallel from the memory cell array 40 and is held in the planar buffer part 200.

In response to the data readout command, the control circuit 13 allows the planar buffer part 200 to hold the readout data and sequentially output the held readout data to the outside.

In writing data in the semiconductor device 1, when address information, for example, a data writing command, and write data are input to the semiconductor device 1, the control circuit 13 allows the planar buffer part 200 to hold the write data. Then, the address decoder 11 generates the SGD0 to SGD15 signals, the SGS signal, and the CG0 to CG31 signals for selecting the memory cell MC to be read out on the basis of the input address information, and the control circuit 13 writes data of a predetermined data length (bit width) in parallel by applying a write voltage to the memory cell array 40 from the voltage generation circuit 12.

As described above, the semiconductor device 1 according to the present embodiment includes the memory semiconductor chip 10 and the TSV 30 (electrical connection structure). The memory semiconductor chip 10 includes the plurality of memory cells MC. The planar buffer chip 20 is a semiconductor chip that includes a plurality of buffer circuits 21 which hold data read from the memory cell MC and data written to the memory cell MC and which output the held data in accordance with the number of readout lines (bit lines) of the plurality of memory cells MC. The TSV 30 electrically connects the readout line of the memory cell MC of the memory semiconductor chip 10 to the buffer circuit 21 of the planar buffer chip 20 in the thickness direction of the memory semiconductor chip 10 and the planar buffer chip 20.

Thereby, the buffer circuits 21 can be arranged in a two-dimensional plane form (for example, an XY-plane form) on the planar buffer chip 20, and therefore, the semiconductor device 1 according to the present embodiment can perform access (reading and writing) to more memory cells MC in parallel. Thereby, the semiconductor device 1 according to the present embodiment can speed up the access.

For example, a one-dimensional line access in the related art is changed to a two-dimensional surface access by the semiconductor device 1 according to the present embodiment, and thereby, it is possible to improve the access speed, for example, by one digit or two digits. For example, in the related art, the throughput is 16 MB/s for writing 16 KB (kilobytes) of one page 1 in 1 ms (milliseconds).

On the other hand, in the semiconductor device 1 according to the present embodiment, for example, ten pages (160 KB) can be processed in parallel, and the throughput can be increased to 160 MB/s.

Further, since the semiconductor device 1 according to the present embodiment electrically connects the readout line of the memory cell MC and the buffer circuit 21 of the planar buffer chip 20 three-dimensionally in the thickness direction (Z-axis direction), for example, the connection by the wiring on the plane of the semiconductor chip as in the related art is not required, and the wiring pitch on the plane does not limit the wiring routing. Therefore, the semiconductor device 1 according to the present embodiment can reduce the chip size of the memory semiconductor chip 10.

Further, in the present embodiment, in the memory semiconductor chip 10, the plurality of gate plate electrodes (10-SGS, 10-0, . . . , 10-30, 10-31, 10-SGD) including the memory cell MC are laminated in the thickness direction. The TSV 30 electrically connects the plurality of laminated gate plate electrodes (10-SGS, 10-0, . . . , 10-30, 10-31, 10-SGD) to the planar buffer chip 20.

Thereby, the semiconductor device 1 according to the present embodiment has a memory semiconductor chip 10 (memory cell array 40) defined in a three-dimensional manner, and it is possible to further reduce the chip size of the memory semiconductor chip 10 and to further speed up the access.

Further, in the present embodiment, the TSV 30 is a penetration electrode that penetrates through the memory semiconductor chip 10 and the planar buffer chip 20 in the thickness direction and that connects the memory semiconductor chip 10 and the planar buffer chip 20 using a conductor. That is, the TSV 30 is a bumpless penetration electrode.

Thereby, the semiconductor device 1 according to the present embodiment can significantly reduce the pitch of the TSV 30, for example, compared to a case using a bump of the related art, and further more buffer circuits 21 can be arranged on the planar buffer chip 20. Therefore, the semiconductor device 1 according to the present embodiment can further reduce the chip size and can further speed up the access.

Further, since the TSV 30 can thin the semiconductor chip compared to the bump of the related art, it is possible to reduce the impedance of the connection. Therefore, the semiconductor device 1 according to the present embodiment can reduce the noise and further speed up the access.

### Second Embodiment

Next, a semiconductor device 1a according to a second embodiment will be described with reference to the drawings.

FIG. 8 is a configuration view showing an example of the semiconductor device 1a according to the second embodiment.

As shown in FIG. 8, the semiconductor device 1a is, for example, a NAND-type flash memory device and includes a memory semiconductor chip 10, a decoder chip 10A, a planar buffer chip 20, and a TSV 30.

In FIG. 8, the same reference numeral is given to the same configuration as that in FIG. 1 described above, and description thereof is omitted.

The decoder chip 10A includes a buffer decoder part 50 that selects one buffer circuit 21 from a predetermined number of readout lines (bit lines).

In the present embodiment, the memory semiconductor chip 10 and the planar buffer chip 20 are connected by the TSV 30 via the decoder chip 10A.

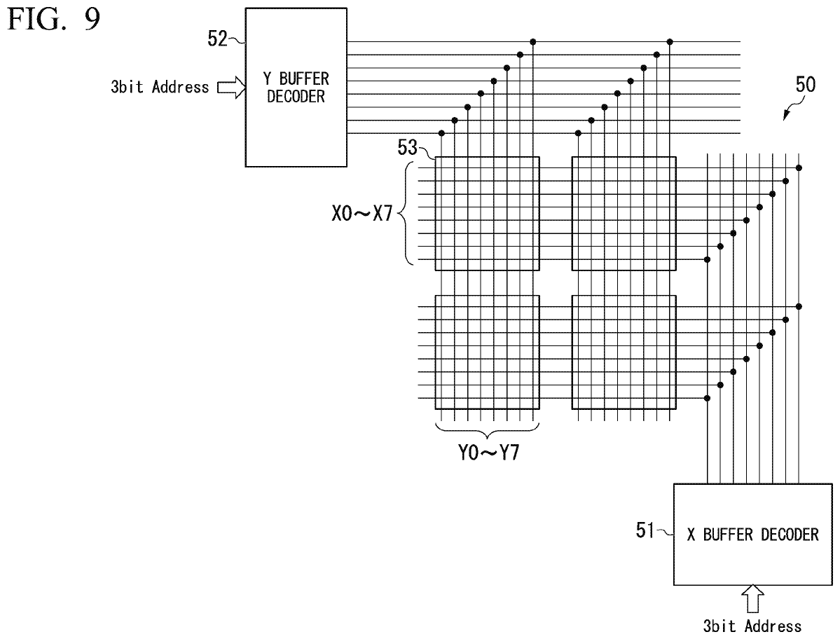

Next, the configuration of the buffer decoder part 50 will be described with reference to FIG. 9 to FIG. 11.

FIG. 9 is a configuration view showing an example of the buffer decoder part 50 according to the present embodiment.

As shown in FIG. 9, the buffer decoder part 50 includes an X buffer decoder 51, a Y buffer decoder 52, and a decoder switch part 53.

The X buffer decoder 51 decodes three bits of the address information and generates a selection signal of X0 to X7.

The Y buffer decoder 52 decodes three bits of the address information that are different from those of the X buffer decoder 51 and generates a selection signal of Y0 to Y7.

The decoder switch part 53 selects one from sixty-four readout lines and connects the one selected readout line to the buffer circuit 21 on the basis of the combination of the selection signal of X0 to X7 generated by the X buffer decoder 51 with the selection signal of Y0 to Y7 generated by the Y buffer decoder 52.

In the present embodiment, one buffer circuit 21 is connected to one decoder switch part 53 by the TSV 30.

Further, one NAND string NS is connected to each of the sixty-four readout lines.

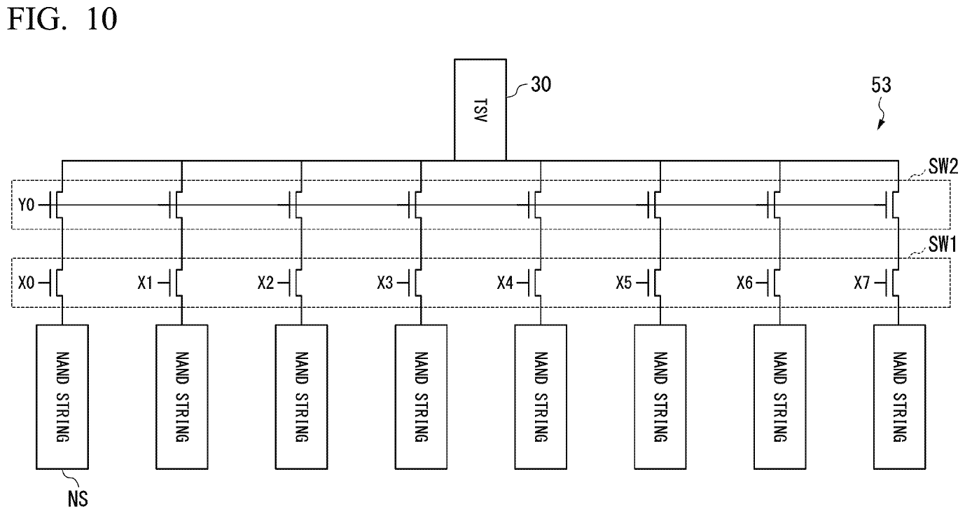

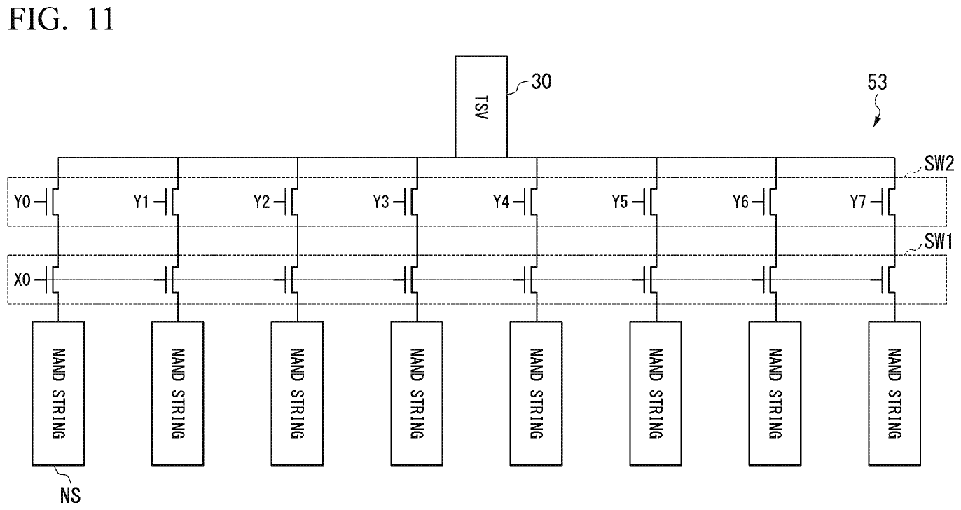

Next, the configuration of the decoder switch part 53 will be described with reference to FIG. 10 and FIG. 11.

FIG. 10 is a configuration view in a case of selecting the Y0 line of the decoder switch part 53 according to the present embodiment. FIG. 11 is a configuration view in a case of selecting the X0 line of the decoder switch part 53 according to the present embodiment.

As shown in FIG. 10 and FIG. 11, the decoder switch part 53 includes a selection switch part SW1 and a selection switch part SW2.

The selection switch part SW1 is a selection switch that is controlled by the selection signal of X0 to X7 generated by the X buffer decoder 51. The selection switch part SW2 is a selection switch that is controlled by the selection signal of Y0 to Y7 generated by the Y buffer decoder 52.

The decoder switch part 53 selects one from sixty-four NAND strings NS by a matrix of the selection switch part SW1 with the selection switch part SW2 and connects the selected one NAND string NS to the buffer circuit 21 by the TSV 30.

The connection between the decoder switch part 53 and each NAND string NS is an electrical connection using polysilicon or the like similarly to that in the NAND string NS.

The selection switch part SW1 and selection switch part SW2 are arranged on decoder chip 10A.

As described above, the semiconductor device 1a according to the present embodiment includes the memory semiconductor chip 10, the planar buffer chip 20, and the TSV 30 (electrical connection structure) described above and further includes the buffer decoder part 50. The buffer decoder part 50 selects one from a predetermined number (for example, sixty-four) of readout lines and connects the selected one readout line to the buffer circuit 21.

Thereby, the semiconductor device 1a according to the present embodiment can select one from the appropriate number of readout lines and connect the selected one readout line to the buffer circuit 21 in accordance with the size of the buffer circuit 21.

The present invention is not limited to the above-described embodiments, and modifications can be made without departing from the scope of the present invention.

For example, the above embodiments are described using an example in which the memory cell array 40 is a NAND-type memory array in which the memory cells MC are three-dimensionally arranged; however, the embodiment is not limited thereto. The present invention may be applied to a memory array in which the memory cells MC are arranged in a planar form on the memory semiconductor chip 10.

The above embodiments are described using an example in which the memory semiconductor chip 10 is connected to the planar buffer chip 20 by the TSV 30; however, the embodiment is not limited thereto. The memory semiconductor chip 10 may be connected to the planar buffer chip 20 by another electrical connection structure such as a bump.

The above embodiments are described using an example in which the semiconductor device 1 (1a) is a flash memory device; however, the embodiment is not limited thereto. The present invention may be applied to another semiconductor memory.

The above embodiments are described using an example in which the planar buffer chip 20 is arranged on the upper side of the memory semiconductor chip 10; however, the embodiment is not limited thereto. The planar buffer chip 20 may be arranged on the lower side of the memory semiconductor chip 10, or the memory semiconductor chip 10 may be arranged on the upper and lower sides of the planar buffer chip 20.

The above second embodiment is described using an example in which the buffer decoder part 50 is arranged on a different decoder chip 10A than the planar buffer chip 20 but may be arranged together with the buffer circuit 21 on the planar buffer chip 20.

For example, one buffer circuit 21 may be connected to one NAND string NS by the TSV 30 without the buffer decoder part 50.

What is claimed is:

1. A semiconductor device comprising:
a memory semiconductor chip that comprises a plurality of memory cells;
a planar buffer chip as a semiconductor chip that comprises a plurality of buffer circuits which hold data read from the memory cell and data written to the memory cell and which output the held data in accordance with a number of readout lines of the plurality of memory cells; and
an electrical connection structure that electrically connects the readout line of the memory cell of the memory semiconductor chip to the buffer circuit of the planar buffer chip in a thickness direction of the memory semiconductor chip and the planar buffer chip.

2. The semiconductor device according to claim 1, comprising
a buffer decoder part that is configured to select one from a predetermined number of readout lines and connects the selected one readout line to the buffer circuit.

3. The semiconductor device according to claim 1,
wherein the memory semiconductor chip has a plurality of semiconductor chips including the memory cell that are laminated in a thickness direction, and
the electrical connection structure electrically connects the plurality of laminated semiconductor chips to the planar buffer chip.

4. The semiconductor device according to claim 2,
wherein the memory semiconductor chip has a plurality of semiconductor chips including the memory cell that are laminated in a thickness direction, and
the electrical connection structure electrically connects the plurality of laminated semiconductor chips to the planar buffer chip.

5. The semiconductor device according to claim 1,
wherein the electrical connection structure is a penetration electrode that penetrates through the memory semiconductor chip and the planar buffer chip in a thickness direction and connects the memory semiconductor chip to the planar buffer chip using a conductor.

6. The semiconductor device according to claim 2,
wherein the electrical connection structure is a penetration electrode that penetrates through the memory semiconductor chip and the planar buffer chip in a thickness direction and connects the memory semiconductor chip to the planar buffer chip using a conductor.

7. The semiconductor device according to claim 3,
wherein the electrical connection structure is a penetration electrode that penetrates through the memory semiconductor chip and the planar buffer chip in a thickness direction and connects the memory semiconductor chip to the planar buffer chip using a conductor.

8. The semiconductor device according to claim 4,
wherein the electrical connection structure is a penetration electrode that penetrates through the memory semiconductor chip and the planar buffer chip in a thickness direction and connects the memory semiconductor chip to the planar buffer chip using a conductor.
